(19) United States
(12) Patent Application Publication
(10) Pub. No.: US 2001/0013643 A1
(43) Pub. Date: Aug. 16, 2001

(54) SEMICONDUCTOR INTEGRATED CIRCUIT DEVICE

(76) Inventors: HIROYUKI NAKANISHI, KITAKATSURAGI-GUN (JP); TOSHIYA ISHIO, NARA-SHI (JP); YOSHIHIDE IWAZAKI, TENRI-SHI (JP); KATSUNOBU MORI, NARA-SHI (JP)

Correspondence Address: BIRCH STEWART KOLASCH & BIRCH, PO BOX 747, FALLS CHURCH, VA, 22040-0747, US

(21) Appl. No.: 09/373,004

(22) Filed: Aug. 12, 1999

(30) Foreign Application Priority Data
Sep. 18, 1998 (JP) 10-265309

(51) Int. Cl. H01L 23/02

(52) U.S. Cl. 257/678

(57) ABSTRACT

A plurality of semiconductor chips are mounted and sealed with a resin layer. Each of the semiconductor chips is secured by a surface thereof opposite to an element forming surface onto either side of a die pad, and at least a pair of the semiconductor chips are secured on at least one side of the die pad so that the element forming surfaces thereof face each other, and first electrode sections provided on the element forming surfaces are coupled together by a conductive coupling material. Therefore, a semiconductor integrated circuit device having many semiconductor chips fitted in a single package can be easily fabricated while restraining increases in the down-set value of the die pad from the reference surface and maintaining a high level of accuracy.

### FIELD OF THE INVENTION

The present invention relates to semiconductor integrated circuit devices having a plurality of semiconductor integrated circuit chips.

### BACKGROUND OF THE INVENTION

Conventionally, there is a variety of semiconductor integrated circuit devices incorporating only a single semiconductor integrated circuit chip (hereinafter will be simply referred to as a semiconductor chip). For example, Japanese Laid-Open Patent Application No. 63-179554/1988 (Tokukaisho 63-179554, published on Jul. 23, 1988) discloses such a semiconductor integrated circuit device having an arrangement shown in FIG. 10 (first prior art). The semiconductor integrated circuit device, typically, is fabricated as below.

First, a semiconductor chip 53 is bonded by a thermosetting silver paste 52 onto a die pad 51 provided to a leadframe (not shown).

Next, the silver paste 52, which contains a solvent, is caused to cure so as to secure the semiconductor chip 53 to the die pad 51.

Next, the inner lead sections 54a of the leads 54 provided to the leadframe are bonded to a bonding pad (not shown) provided to the element forming surface (top surface in FIG. 10) of the semiconductor chip 53 by bonding wires 55 made of fine gold and other lines.

Subsequently, this is sealed with a sealant resin layer 56 such as an epoxy resin. Thereafter, a finishing touch is given by cutting off support leads (not shown) provided to support the die pad 51 as well as tie bars (not shown) provided to the leadframe to prevent the resin of the sealant resin layer 56 from flowing into between outer lead sections 54b of the leads 54, and then bending the outer lead sections 54b in a desired shape. Note that a resin coating film 58 is applied to a surface of the die pad 51 opposite to the element forming surface.

Meanwhile, in response to increasing demands for denser and thinner integrated circuits in recent years, it is suggested that advanced arrangements be applied to the semiconductor integrated circuit devices. Japanese Laid-Open Utility Model Publication No. 62-147360/1987 (Jitsukaisho 62-147360, published on Sep. 17, 1987) and Japanese Laid-Open Patent Application No. 8-213412/1996 (Tokukaihei, 8-213412 published on Aug. 20, 1996) disclose such semiconductor integrated circuit devices having semiconductor chips 53a and 53b mounted respectively on the front and back surfaces of a die pad 51 as shown in FIG. 11 (second prior art).

In the semiconductor integrated circuit device, the semiconductor chips 53a and 53b are configured so that the back surfaces thereof (those surfaces of the semiconductor chips 53a and 53b opposite to the element forming surfaces) face each other sandwiching the die pad 51. The semiconductor integrated circuit device is fabricated as below.

First, the semiconductor chips 53a and 53b are coupled (die bonded) to the respective surfaces of the die pad 51 by the silver paste 52 so that the element forming surfaces face outward, and thereafter the silver paste 52 is caused to cure.

Next, the inner lead sections 54a are bonded to bonding pads provided to the element forming surfaces of the semiconductor chips 53a and 53b by bonding wires 55 made of fine gold and other lines. The succeeding process is identical to that mentioned earlier, including the sealing with the sealant resin layer 56, cutting-off of the tie bars and the support leads, and bending of the outer lead sections 54b.

Japanese Publication for Examined Patent Application No. 58-45822/1983 (Tokukosho 58-45822, published on Oct. 12, 1983 discloses another example of the semiconductor integrated circuit device having semiconductor chips that are stacked in layers. As shown in FIG. 12, the semiconductor integrated circuit device has two semiconductor chips 53c and 53d; the semiconductor chip 53c is coupled on a surface thereof opposite to the element forming surface to a die pad 51 by the silver paste 52, and the semiconductor chips 53c and 53d are bonded together by a conductive coupling material 59, rather than by a wire, so that the element forming surfaces face each other. The inner lead sections 54a are wire bonded to the semiconductor chip 53c (third prior art).

Japanese Laid-Open Patent Application No. 5-90486/1993 (Tokukaihei 5-90486, published on Apr. 9, 1993) and Japanese Laid-Open Patent Application No. 9-186289/1997 (Tokukaihei 9-186289, published on Jul. 15, 1997) disclose further examples of the semiconductor integrated circuit device having semiconductor chips that are stacked in layers. The semiconductor integrated circuit device has a structure whereby a semiconductor chip with an upward-looking element forming surface and a semiconductor chip with a downward-looking element forming surface are alternately stacked in layers. In the structure, the semiconductor chips of which the element forming surfaces face each other are coupled by bumps, and a bonding pad provided to the semiconductor chip having an upward element forming surface serves as a terminal for external connections (fourth prior art).

Most semiconductor integrated circuit devices manufactured recently are fabricated in a standardized package having a uniform appearance, where a heat-molten epoxy resin is injected and molded in a die to coat, i.e. seal, a semiconductor chip or semiconductor chips.

Further, the semiconductor chip is typically secured to a die pad, i.e., a patterned region provided in a leadframe to secure the semiconductor chip. During the injection molding, the die pad is lowered (down set) from a reference surface to stabilize liquidification balance of the sealing-use resin. In the case of the aforementioned third prior art, since there are two stacked semiconductor chips, the semiconductor chips can be easily packaged by lowering the die pad from the reference surface about half the total thickness of the stacked semiconductor chips

Meanwhile, in the structure disclosed in the aforementioned fourth prior art, three or more semiconductor chips are stacked in layers in a single direction from the reference surface, i.e., in the upward direction. When the stacked semiconductor chips are secured within the semiconductor integrated circuit device, only the back surface of the lowest semiconductor chip is coupled to the die pad. Therefore, if the stacked semiconductor chips are mounted in a leadframe provided with the aforementioned die pad, the die pad needs to be lowered by a greater value, causing it difficult to fabricate a semiconductor integrated circuit device while maintaining a high level of accuracy.

In other words, to increase the down set, a part of the lead frame needs to be set aside to serve as a plastic deformation area, which would negatively contribute to the reduction of the package in size. If the down set is increased without reserving (deforming) a plastic deformation area, the amount of plastic deformation of the metal increases, and the metal becomes weaker, resulting in lower accuracy (finish tolerance) in manufacturing.

Accordingly, by reducing the thickness of the semiconductor chips, it may be possible to lower the die pad by a smaller value. However, to reduce the thickness of the semiconductor chips, the wafer from which the semiconductor chips are fabricated needs to be reduced in thickness. In addition, reducing the thickness of the wafer, which recently has increased in size, would render the wafer vulnerable to cracks and a break-up during processing, and therefore is very difficult.

Further, if the semiconductor chips having the same function are to be stacked in layers, it is preferable to reduce those common signal lines extending to the outside by coupling as many common signal lines together as possible. However, in the case of such an arrangement, a design needs to be made on the configuration of electrode pads so that the electrode pads are coupled together for each semiconductor chip, resulting in a problem that the designing becomes complicated.

Further, in an arrangement whereby stacked semiconductor chips are sealed with a resin, the variations and balance of the intervals between the stacked semiconductor chips increasingly deteriorate as more semiconductor chips are incorporated in the semiconductor integrated circuit device or as the semiconductor integrated circuit device becomes thinner. To restrain the deterioration, it is necessary to maintain a high level of accuracy with the semiconductor chip intervals.

### SUMMARY OF THE INVENTION

It is an object of the present invention to offer a semiconductor integrated circuit device having a plurality of semiconductor chips that are mounted thereon and are sealed with a resin layer, which is capable of restraining increases in the down-set value of the die pad from the reference surface and is easily fabricated while maintaining a high level of accuracy.

To achieve the above object, a semiconductor integrated circuit device in accordance with the present invention is characterized in that it includes:

a first semiconductor chip provided on each side of a die pad so that a surface opposite to an element forming surface faces the die pad;

a multilayer structure provided on at least one side of the die pad, the structure including at least one semiconductor chip pair composed of the first semiconductor chip and a second semiconductor chip that is coupled to the first semiconductor chip so that the element forming surfaces of the first and second semiconductor chips face each other; and

a resin layer for sealing a stack body composed of the die pad and the first and second semiconductor chips.

With the foregoing arrangement, each side of the die pad has at least the first semiconductor chip. Further, at least one of the sides of the die pad has a multilayer structure including at least one semiconductor chip pair. The semiconductor chip pair is composed of the first semiconductor chip and the second semiconductor chip. The first semiconductor chip is provided so that the surface opposite to the element forming surface thereof faces the die pad, whereas the second semiconductor chip is coupled to the first semiconductor chip so that the element forming surfaces of the first and second semiconductor chips face each other.

In conventional semiconductor integrated circuit devices, a plurality of semiconductor chips were stacked in layers only on the top side of the die pad. With that structure, it was necessary to stabilize the liquidification balance of a sealing-use resin by increasing the down-set value of the die pad, that is, by positioning the die pad far below the reference surface. Therefore, it was very difficult to fabricate semiconductor integrated circuit devices while maintaining a high level of accuracy.

By contrast, with the arrangement of the present application, each side of the die pad has a semiconductor chip, and a plurality of semiconductor chips are stacked in layers not only on the top side of the die pad. In other words, the plurality of semiconductor chips, since being positioned on both sides of the die pad so as to sandwich the die pad, are less bulky in the thickness direction of the semiconductor integrated circuit device and makes more efficient use of the space available in the semiconductor integrated circuit device, than otherwise arranged.

Therefore, a semiconductor integrated circuit device having many semiconductor chips fitted in a single package can be easily fabricated while restraining the down-set value of the die pad from the reference surface and maintaining a high level of accuracy.

The present invention will become more fully understood from the detailed description given hereinbelow and the accompanying drawings which are given by way of illustration only, are not in any way intended to limit the scope of the claims of the present invention.

### BRIEF DESCRIPTION OF THE DRAWINGS

FIG. 1 is a vertical cross-sectional view showing a semiconductor integrated circuit device of an embodiment in accordance with the present invention.

FIG. 2 is a transparent perspective view showing the interior of the semiconductor integrated circuit device shown in FIG. 1.

FIG. 3 a plan view showing the semiconductor integrated circuit device shown in FIG. 1.

FIG. 4 is an exploded perspective view showing a first stack body of the semiconductor integrated circuit device shown in FIG. 1.

FIG. 5 is an exploded perspective view showing the first stack body, a die pad, and a second stack body of the semiconductor integrated circuit device shown in FIG. 1.

FIG. 6 is a vertical cross-sectional view showing a semiconductor integrated circuit device of another embodiment in accordance with the present invention.

FIG. 7 is a vertical cross-sectional view showing a semiconductor integrated circuit device of even another embodiment in accordance with the present invention.

FIG. 8 is a vertical cross-sectional view showing a semiconductor integrated circuit device provided with a coating film made of a coating resin.

FIG. 9 is a vertical cross-sectional view showing a semiconductor integrated circuit device of still another embodiment in accordance with the present invention.

FIG. 10 is a vertical cross-sectional view showing a conventional semiconductor integrated circuit device.

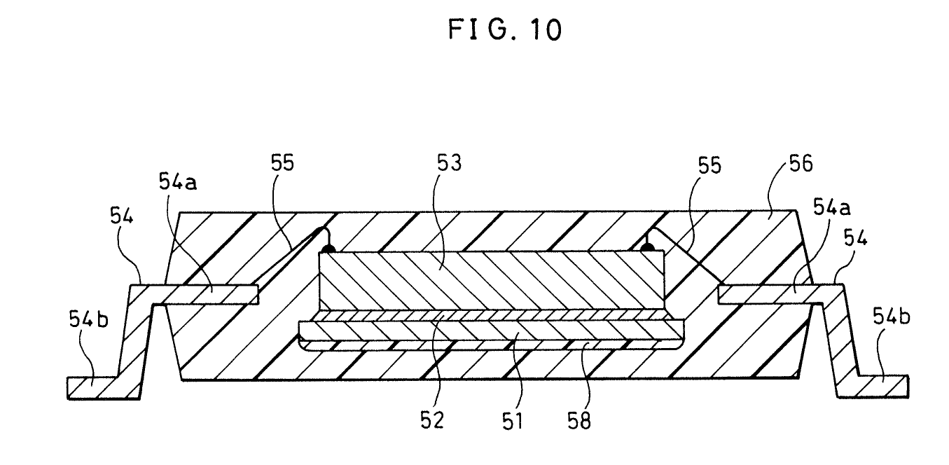

FIG. 11 is a vertical cross-sectional view showing another conventional semiconductor integrated circuit device.

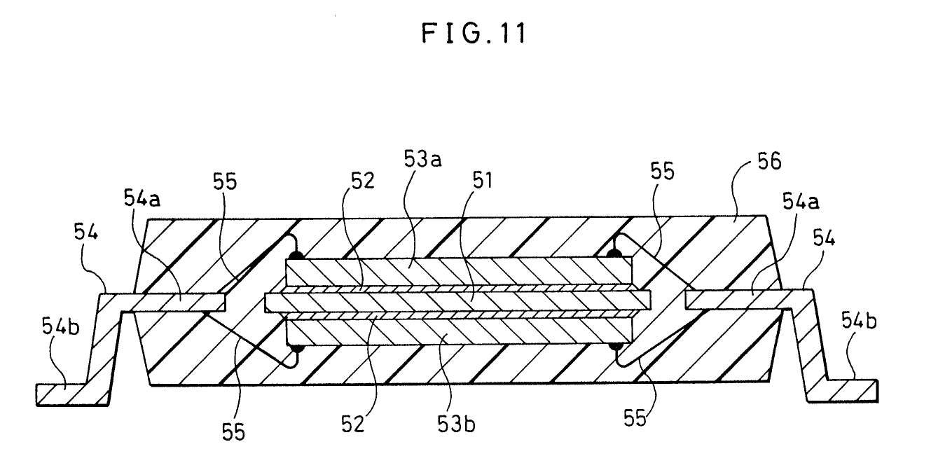

FIG. 12 is a vertical cross-sectional view showing even another conventional semiconductor integrated circuit device.

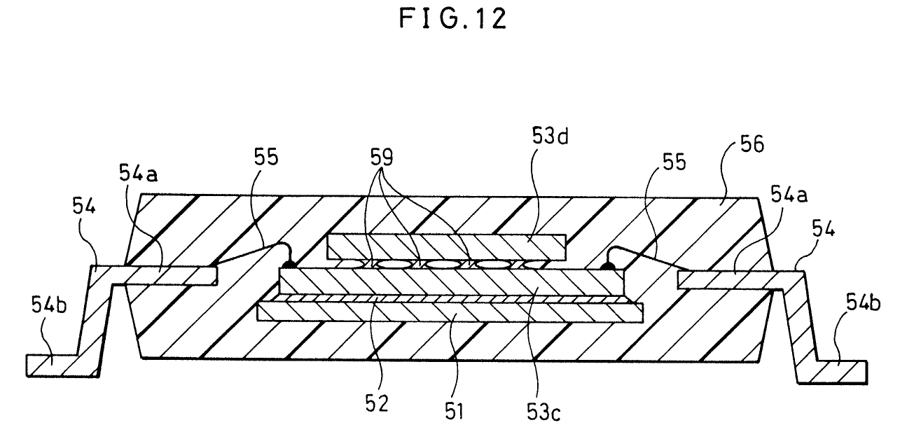

### DESCRIPTION OF THE EMBODIMENTS

Embodiment 1

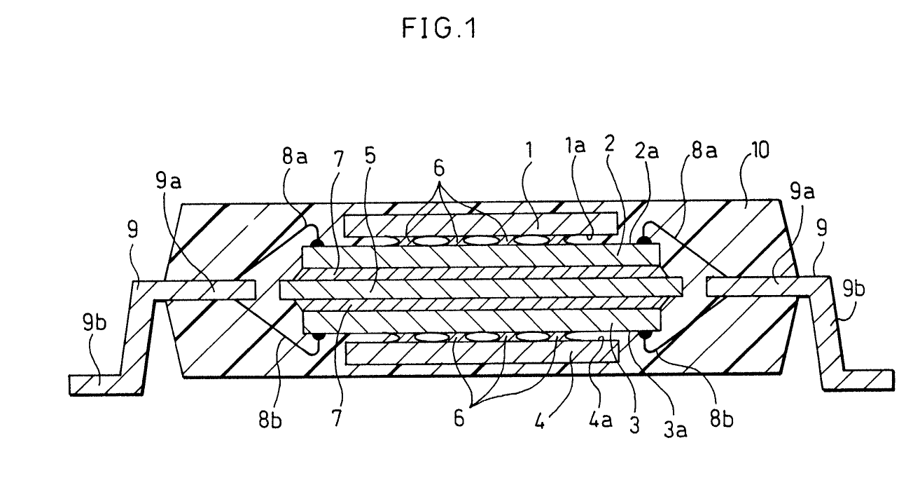

Referring to FIG. 1 to FIG. 5, the following description will explain an embodiment in accordance with the present invention.

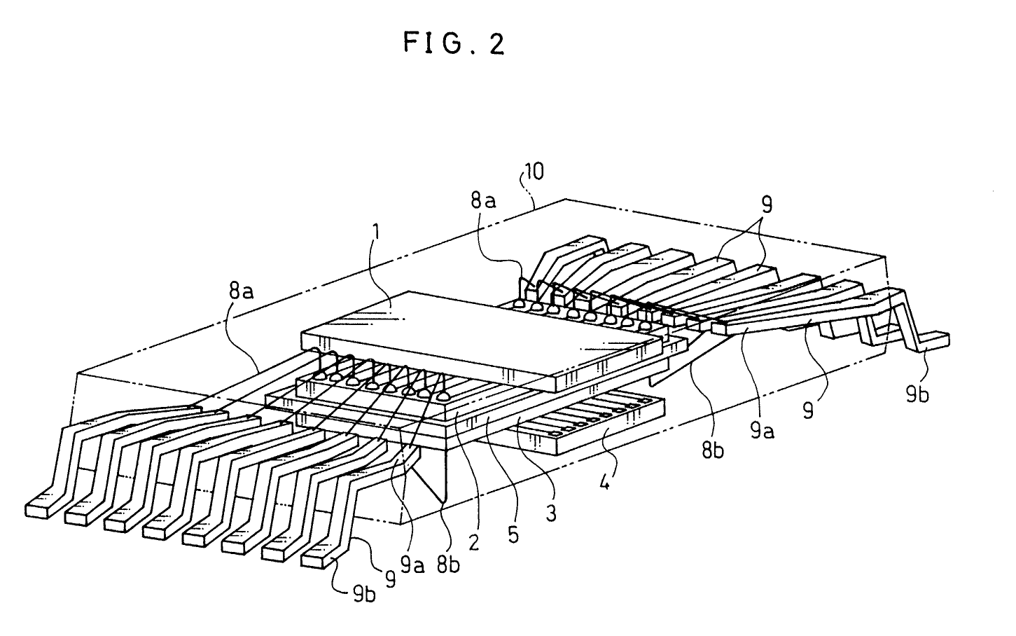

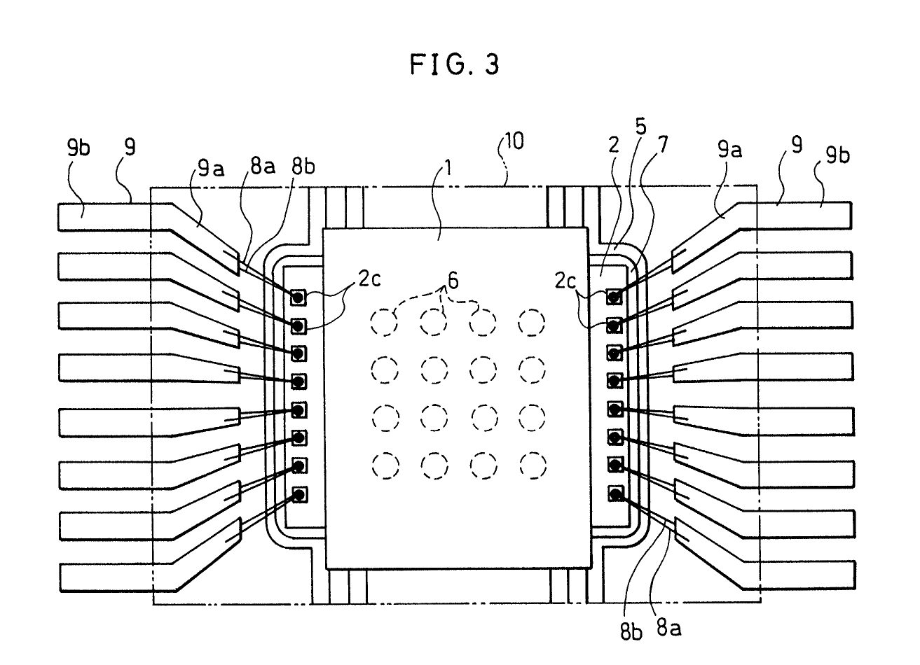

The semiconductor integrated circuit device of the present embodiment has the arrangement shown in FIG. 1 to FIG. 3. Note that FIG. 1 is a vertical cross-sectional view, FIG. 2 is a transparent perspective view, and FIG. 3 is a plan view of the semiconductor integrated circuit device.

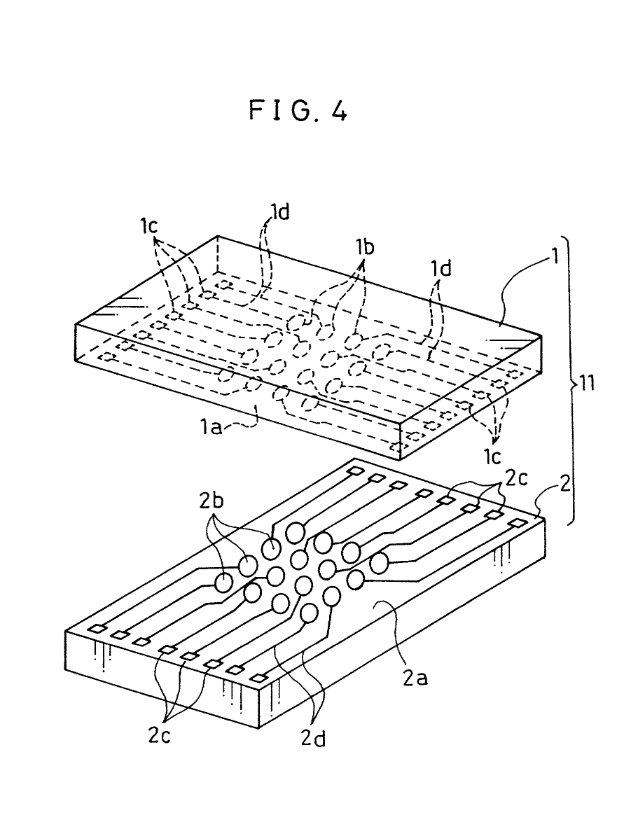

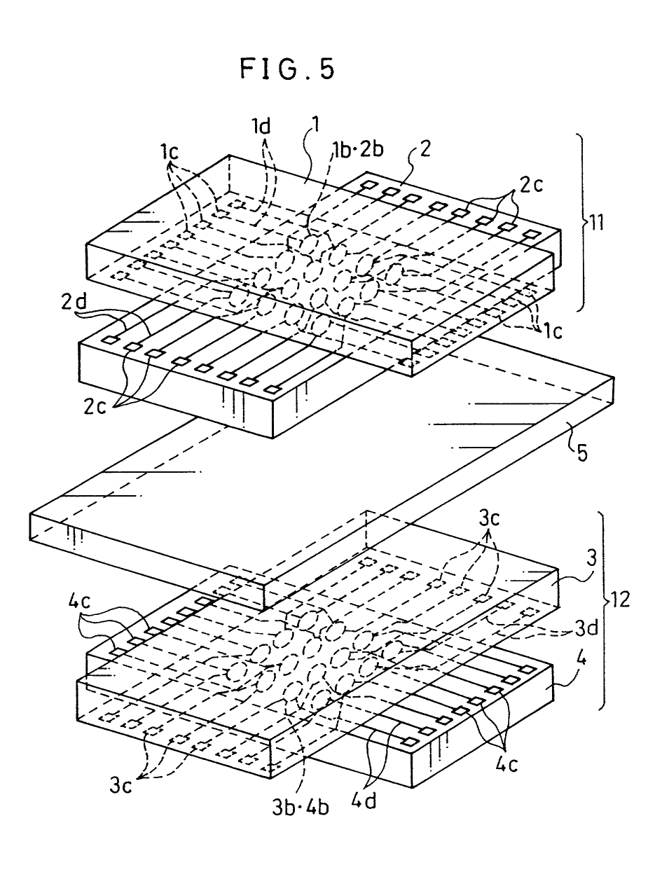

The semiconductor integrated circuit device includes semiconductor chips 1 and 2 on the top side of a die pad 5 and semiconductor chips 3 and 4 on the bottom side of the die pad 5. As shown in FIG. 4 and FIG. 5, the semiconductor chips 1 to 4 are plates of a rectangular shape; the semiconductor chips 1 and 2 are arranged so that the respective element forming surfaces (active surfaces) 1a and 2a face each other, whereas the semiconductor chips 3 and 4 are arranged so that the respective element forming surfaces (active surfaces) 3a and 4a face each other. The semiconductor chips (first semiconductor chips) 2 and 3 are arranged so that the surfaces thereof opposite to the element forming surfaces 2a and 3a face the die pad 5, whereas the semiconductor chips (second semiconductor chips) 1 and 4 are arranged so that the element forming surfaces 1a and 4a thereof face the die pad 5.

As shown in FIG. 4, the semiconductor chips 1 and 2 are provided near the centre of the element forming surfaces 1a and 2a with many first electrode pads (first electrode sections) 1b and 2b, while the element forming surfaces 1a and 2a are provided along longitudinal ends thereof with many wire-bonding-use second electrode pads (second electrode sections) 1c and 2c. The second electrode pads 1c and 2c are connected to the first electrode pads 1b and 2b by conductive wiring patterns Id and 2d provided on the element forming surfaces 1a and 2a. Note that the first electrode pads 1b and 2b, the second electrode pads 1c and 2c, and the wiring patterns 1d and 2d are provided on insulating layers (not shown) provided on the respective element forming surfaces la and 2a.

As shown in FIG. 1, the semiconductor chips 1 and 2 are electrically connected and joined together by coupling the first electrode pads 1b and 2b with a conductive paste material 6. The semiconductor chips 3 and 4 have the same arrangement as the semiconductor chips 1 and 2 with respect to the interconnection therebetween and the inclusion of the first electrode pads 1b and 2b, the second electrode pads 1c and 2c, and the wiring patterns 1d and 2d. As shown in FIG. 5, the semiconductor chips 3 and 4 include first electrode pads (first electrode sections) 3b and 4b, second electrode pads (second electrode sections) 3c and 4c, and wiring patterns 3d and 4d. Further, the semiconductor chips 1 and 2, being stacked in layers, constitute a first stack body 11, whereas the semiconductor chips 3 and 4, being stacked in layers, constitute a second stack body 12.

The semiconductor chip 2 is secured to the top surface of the die pad 5 by coupling a surface of the semiconductor chip 2 opposite to the element forming surface 2a to the die pad 5 with a die coupling material 7. Similarly, the semiconductor chip 3 is secured to the bottom surface of the die pad 5 by coupling a surface of the semiconductor chip 3 opposite to the element forming surface 3a to the die pad 5 with the die coupling material 7.

The second electrode pad 2c of the semiconductor chip 2 is connected to an inner lead section 9a of a lead 9, which also has an outer lead section 9b, by a metal line 8a that serves as a bonding wire. Similarly, the second electrode pad 3c of the semiconductor chip 3 is connected to the inner lead section 9a of the lead 9 by a metal line 8b.

In the layers including the semiconductor chips 1 to 4 and the die pad 5, i.e., in a semiconductor chip stack body, the metal lines 8a and 8b as well as the inner lead sections 9a of the leads 9 are sealed with a sealant resin layer 10.

Here, the semiconductor integrated circuit device can transmit all electric signals from a member not wire bonded to the lead 9, for example, the semiconductor chip 1 to circuits inside the semiconductor chip 2 through the first electrode pads 1b, the conductive paste material 6, and the first electrode pads 2b. In other words, in the semiconductor integrated circuit device, since the semiconductor chip 1 and the semiconductor chip 2 share common electric signals (hereinafter will be referred to as common signals), the first electrode pads 1b and 2b corresponding to the common signals are electrically connected together, and the semiconductor chips 1 and 2 share the second electrode pads 2c, of the semiconductor chip 2, which are wire bonded to the leads 9. The semiconductor chips 3 and 4 have the same relationship as that between the semiconductor chips 1 and 2 in the sharing of the second electrode pads 2c.

Such an arrangement in, for example, the first stack body 11 including the semiconductor chips 1 and 2 eliminates the need to wire bond the second electrode pads 1c to the leads 9. As a result, the arrangement of the semiconductor integrated circuit device is simplified, allowing easy fabrication of the semiconductor integrated circuit.

In the semiconductor integrated circuit device, the semiconductor chips, namely, the semiconductor chips 1 and 2 and the semiconductor chips 3 and 4, are provided on different sides of the die pad 5. Apart from that, owing to the structure that joins the first electrode pads 1b and 2b together, semiconductor chips, for example, the semiconductor chips 1 and 2, have a restrained dimension in the layer thickness direction and thereby make efficient use of the space. Therefore, in the fabrication of many semiconductor chips, i.e., the semiconductor chips 1 to 4 to fit in a single package, the down-set value of the die pad 5 from the reference surface is decreased, and the semiconductor integrated circuit device can easily be fabricated while maintaining a high level of accuracy.

Apart from that, in the semiconductor integrated circuit device, since common signals are shared by the first stack body 11 including the semiconductor chips 1 and 2 and the second stack body 12 including the semiconductor chips 3 and 4, the second electrode pads 2c and the second electrode pads 3c corresponding to the common signals are wire bonded to the same inner lead sections 9a. In such a case, the second electrode pad 2c of the semiconductor chip 2 is wire bonded to the top surface of the inner lead section 9a, whereas the second electrode pad 3c of the semiconductor chip 3 is wire bonded to the bottom surface of the inner lead section 9a. Therefore, the semiconductor chip 2 shares the leads 9 with the semiconductor chip 3. This allows the semiconductor integrated circuit device to include less leads 9, and the package of the semiconductor integrated circuit device to be reduced in size.

Here, supposing that all the four semiconductor chips 1 to 4 in the semiconductor integrated circuit device are memory integrated circuits having the same functions, for example, flash memories each having an n-bit capacity, the semiconductor integrated circuit device works as a flash memory having a 4n-bit capacity in a single package, however, with less outer leads than four times those of the flash memory having an n-bit capacity. This is because the defined signals such as input signals and address signals can be externally transmitted as common signals through the leads 9 each dedicated to a single type of signal. However, to select a memory integrated circuit to which data is written or from which data is deleted, a plurality of leads 9 are necessary to serve as chip select terminals for selecting one of the semiconductor chips 1 to 4, and the plurality of leads 9 cannot be shared as common signal lines.

Note that in the semiconductor integrated circuit device, the semiconductor chips 1 to 4 each have a thickness of 0.15 mm, the semiconductor chips 1 and 2 of the first stack body 11, as well as the semiconductor chips 3 and 4 of the second stack body 12, are separated from each other by an interval of 0.05 mm, the leadframe constituting the die pad 5 has a thickness of 0.125 mm, and the die coupling material 7 for coupling the semiconductor chips 2 and 3 to the die pad 5 has a thickness of 0.02 mm. As a result, by fitting the four semiconductor chips 1 to 4 into a TSOP (Thin Small Outline Package) of 1 mm in body thickness, a small, thin, large-capacity memory package is obtained.

The following description will explain a method of manufacturing the semiconductor integrated circuit device arranged in the aforementioned manner.

First, the semiconductor chip 2 diced from a wafer is positioned with the element forming surface 2a facing up. The conductive paste material 6 is applied on the first electrode pads 2b by a dispenser.

Next, the semiconductor chip 1 diced from a wafer is positioned using a flip chip bonder with the element forming surface 1a facing down, so as to be correctly placed on the semiconductor chip 2; then the first electrode pads 1b of the semiconductor chip 1 are coupled by the conductive paste material 6 to the first electrode pads 2b of the semiconductor chip 2. Here, the semiconductor chips 1 and 2, being stacked in the aforementioned manner, are put in an oven to cause the conductive paste material 6 to cure. Hence, the first stack body 11 is obtained composed of the semiconductor chips 1 and 2.

Next, similarly to the aforementioned procedures, the second stack body 12 is obtained composed of the semiconductor chips 3 and 4

Next, the die coupling material 7 is applied to the top surface of the die pad 5 with a dispenser. The first stack body 11 is then placed on the die coupling material 7 by a die bonder with the element forming surface 2a of the semiconductor chip 2 facing up, and the die coupling material 7 is scrubbed to spread thin on the die pad 5. Thereafter, the die coupling material 7 is caused to cure in an oven so as to secure the first stack body 11 to the die pad 5.

Next, the leadframe is reversed, and, similarly to the aforementioned procedures, the die coupling material 7 is applied onto the die pad 5 to secure the second stack body 12 onto the top surface of the die coupling material 7.

Although the die coupling material 7 is used here to secure the first stack body 11 and the second stack body 12, alternatively, thermocompression bonding is employed to secure the first stack body 11 and the second stack body 12 to the die pad 5 interposed by a polyimide film.

Next, the second electrode pad 2c of the semiconductor chip 2 is coupled, using a metal line 8a, to the top surface of a predetermined inner lead section 9a by a wire bonder. Then, the leadframe is reversed, and, similarly to the preceding procedures, the second electrode pad 3c of the semiconductor chip 3 is coupled, using a metal line 8b, to the bottom surface of a predetermined inner lead section 9a.

Next, using a molding device, the first stack body 11, the second stack body 12, the die pad 5, and the inner lead section 9a are coated with, and sealed by, an epoxy resin. The sealed body is then put in an oven to cause the epoxy resin, which is to serve as the sealant resin layer 10, to cure.

Finally, the dam pattern between the outer lead sections 9b formed to prevent leakage of the epoxy resin is stamped by a mould. Further, the package of a semiconductor integrated circuit device, which will be the end product, is stamped from the leadframe by a mould, the outer lead sections 9b are bent by a mould in a predetermined shape to complete the manufacturing process of the semiconductor integrated circuit device.

Note that in the present embodiment only one first stack body 11 including a pair of semiconductor chips 1 and 2 is provided on one side of the die pad 5, and only one second stack body 12 including a pair of semiconductor chips 3 and 4 is provided on the other side of the die pad 5. However, two or more first stack bodies 11 and two or more second stack bodies 12 may be provided; specifically, a multilayer structure including one or more pairs of semiconductor chips (one or more first stack bodies 11 and one or more second stack bodies 12) are provided on each surface of the die pad 5. Alternatively, the multilayer structure may be provided only on one side of the die pad 5. When one of these arrangements is employed, there is provided a die coupling material 7 between the first stack bodies 11 and the second stack bodies 12.

Embodiment 2

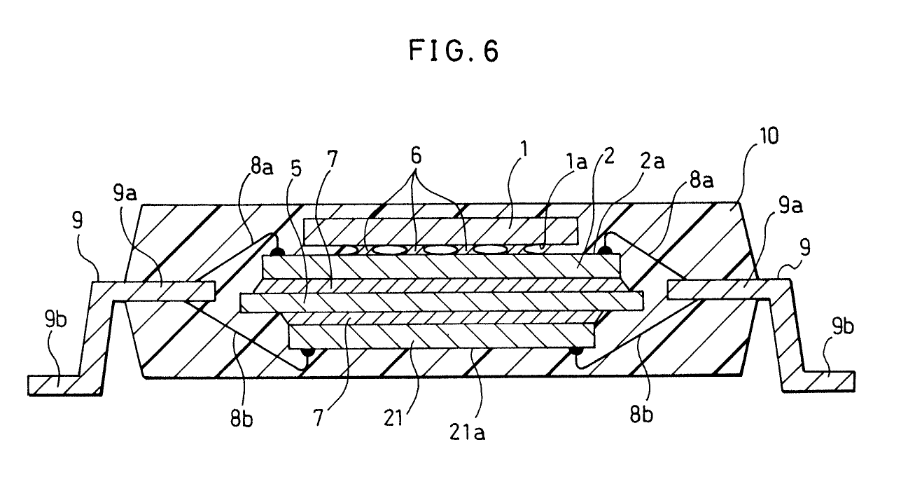

Referring to FIG. 6 to FIG. 9, the following description will explain another embodiment in accordance with the present invention. Here, for convenience, members of the present embodiment that have the same arrangement and function as members of the previous embodiment, and that are mentioned in the previous embodiment are indicated by the same reference numerals and description thereof is omitted.

The semiconductor integrated circuit device shown in FIG. 6 is identical to that shown in FIG. 1, except an arrangement is made thereon to substitute a semiconductor chip 21 for the aforementioned semiconductor chips 3 and 4. The semiconductor chip 21, similarly to the semiconductor chip 3, is coupled on a surface thereof opposite to an element forming surface 21a to a die pad 5 interposed by a die coupling material 7. The semiconductor chip 21 is provided on the element forming surface 21a with second electrode pads (not shown) corresponding to the second electrode pads 3c of the semiconductor chip 3, the second electrode pad being connected to the bottom surface of an inner lead section 9a by a metal line 8b. The semiconductor chip 2 and the semiconductor chip 21 share the leads 9 as the aforementioned common signal lines. The semiconductor integrated circuit device is fabricated basically by the same method as the semiconductor integrated circuit device shown in FIG. 1.

Note that although the semiconductor integrated circuit device is provided with only one first stack body 11 including a pair of semiconductor chips 1 and 2 on a side of the die pad 5, two or more first stack bodies 11 may be stacked to form layers.

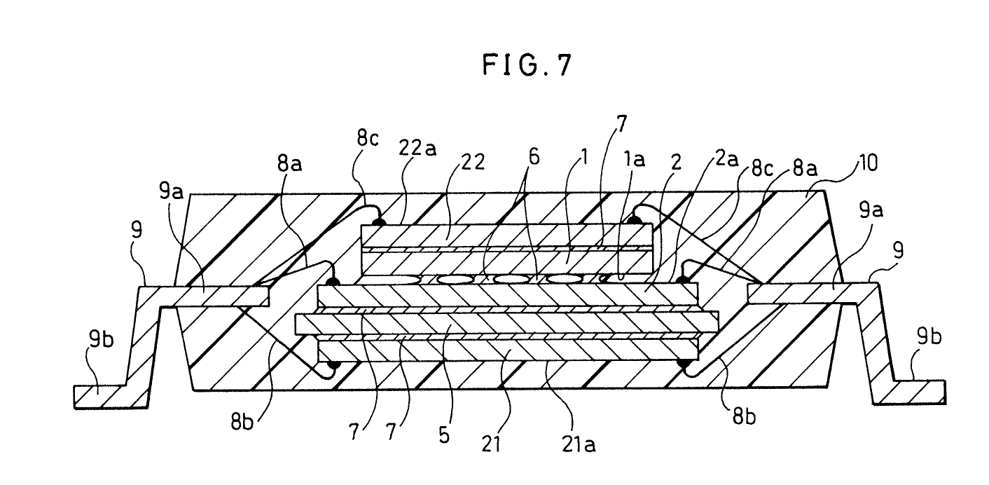

The semiconductor integrated circuit device shown in FIG. 7 is identical to that shown in FIG. 6, except an arrangement is made thereon to dispose a semiconductor chip 22 on the semiconductor chip 1 interposed by a die coupling material 7. The semiconductor chip 1 and the semiconductor chip 22 are coupled to each other on surfaces thereof opposite to respective element forming surfaces 1a and 22a. The semiconductor chip 22 is provided on the element forming surface 22a with second electrode pads (not shown), the second electrode pad being connected to the top surface of an inner lead section 9a by a metal line 8c. The semiconductor chips 2, 21, 22 share the leads 9 as the aforementioned common signal lines. The semiconductor chip 22 and the semiconductor chip 2 are wire bonded simultaneously.

Note that when the semiconductor chip 22 and the semiconductor chip 21 are located at the top and at the bottom respectively with the element forming surfaces 21a and 22a facing outward, as is the case with the present semiconductor integrated circuit device, there is a likelihood that, during a die bonding or wire bonding process, the element forming surface of one of the two semiconductor chips 21 and 22, which is not currently undergoing the bonding process, could come in touch with a tool or instrument and be damaged. However, the damage is avoidable by the use of a method using a supple body disclosed in Japanese Laid-Open Patent Application No. 8-213412/1996 or Japanese Laid-Open Patent Application No. 8-330508.

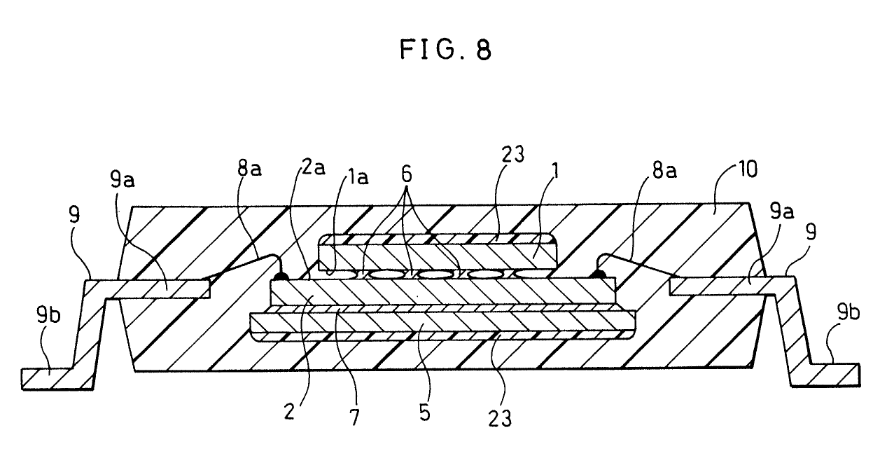

The semiconductor integrated circuit device shown in FIG. 8 includes a resin coating film 23 made of, for example, polyimide formed on a surface opposite to the element forming surface 1a of the semiconductor chip 1, i.e., a surface of the semiconductor chip 1 facing the sealant resin layer 10. The resin coating film 23 is for establishing good adhesion between the semiconductor chip 1 and the sealant resin layer 10. Generally, after the sealant resin layer 10 is molded, the adhesion is likely to come off between the sealant resin layer 10 and the semiconductor chip 1.

In other words, it is typical to find materials of different physical properties being coupled to each other in a complex structure of a semiconductor integrated circuit device including one or more semiconductor chips stacked in layers with or without other components. The semiconductor integrated circuit device is susceptible to forces of a great magnitude that are locally produced due to thermal changes, causing the adhesion to come off at an interface of different materials. Also, since the sealant resin is highly humidity absorbent, when the semiconductor integrated circuit device is mounted on a print substrate, it may be possible that the water content absorbed by the sealant resin is vaporized at the interface where the water content is likely to be condensed, and the resultant pressure of the water vapor exceeds the resistance of, and thus damage, the semiconductor integrated circuit device.

Such a problem is avoidable by the provision of the resin coating film 23. A resin coating film 23 is also provided for the same reason on the side of the die pad 5 facing the sealant resin layer 10.

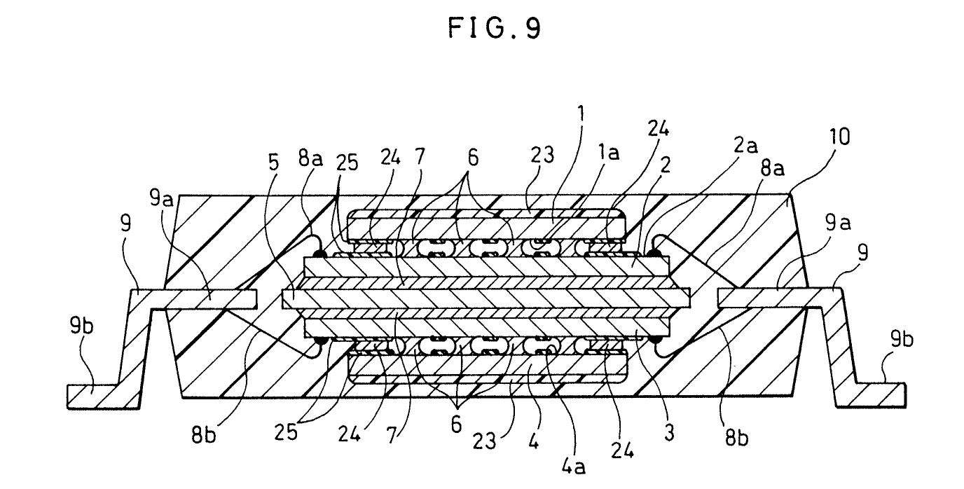

The semiconductor integrated circuit device shown in FIG. 9 is identical to that shown in FIG. 1, except an arrangement is made thereon to dispose a resin coating film 23 on a surface of the semiconductor chip 1 opposite to the element forming surface 1a and on a surface of the semiconductor chip 4 opposite to the element forming surface 4a.

Further, in the semiconductor integrated circuit device, a spacer 24 made of, for example, polyimide is interposed between the semiconductor chips 1 and 2 and between the semiconductor chips 3 and 4. The provision of the spacer 24 to the semiconductor integrated circuit device maintains variations and balance of intervals between the semiconductor chips 1 and 2 and between the semiconductor chips 3 and 4 in predetermined ranges, and realizes a stable, high level of size accuracy in shaping the sealant resin layer 10.

If the interval between the semiconductor chips 1 and 2 should be 0.05 mm, for example, the spacer 24 is set to 0.05 mm in thickness. Note that the spacer 24 is formed, for example, before the semiconductor chips 1 and 2 are stacked by a flip chip bonder, by applying a varnish of polyimide on one of the semiconductor chips with a dispenser and causing the varnish to cure in an oven with a predetermined thickness. Alternatively, a polyimide film formed in a tape shape in advance may be stamped by a mould in a suitable size and coupled to the semiconductor chip 1 or 2.

Between the semiconductor chips 1 and 2, for example, the spacer 24 is preferably disposed along the periphery of the region where the semiconductor chips 1 and 2 are stacked in view of a high level of accuracy in the balance of the intervals between the semiconductor chips 1 and 2. However, the spacer 24 should not cover the second electrode pad 2c.

In addition, for example, by forming a resin coating film 25 of 0.003 to 0.005 (3 to 5 Ìm) mm in thickness on the element forming surfaces 1a and 2a with a spin coater before the semiconductor chips 1 and 2 are diced from a wafer, the element forming surface 2a is protected when the aforementioned polyimide film is stamped in a suitable size by a mould and coupled. Note that since polyimide is used as the coating material, the first electrode pads 2b used for the flip chip bonding and the second electrode pads 2c used for the wire bonding are masked to prevent the first and second electrode pads 2b and 2c from being coated by the coating material during the spin coating.

As mentioned above, the semiconductor integrated circuit device in accordance with the present invention including:

a plurality of semiconductor chips that are mounted thereon and sealed with a resin layer,

wherein the semiconductor chip is secured by a surface thereof opposite to an element forming surface onto either side of a die pad, and

at least a pair of the semiconductor chips are secured on at least one side of the die pad so that the element forming surfaces thereof face each other, and first electrode sections provided on the element forming surfaces are coupled together by a conductive coupling material.

With the foregoing arrangement, the semiconductor chips are secured on both sides of the die pad, and at least a pair of semiconductor chips are secured on at least one side of the die pad so that the element forming surfaces thereof face each other, and the first electrode sections provided on the element forming surfaces are coupled together by a conductive coupling material. Consequently, the plurality of semiconductor chips, since being positioned on both sides of the die pad so as to sandwich the die pad, are less bulky in the thickness direction of the semiconductor integrated circuit device and makes more efficient use of the space available in the semiconductor integrated circuit device, than otherwise arranged.

Therefore, a semiconductor integrated circuit device having many semiconductor chips fitted in a single package can be easily fabricated while restraining the down-set value of the die pad from the reference surface and maintaining a high level of accuracy.

Alternatively, the aforementioned semiconductor integrated circuit device may be arranged so that one of the pair of the semiconductor chips, which is closer to the die pad than the other, is provided on an end of the element forming surface thereof with external-connection-use second electrode sections, and

each of the second electrode sections is connected to one of the first electrode sections of the semiconductor chip that has the second electrode sections by a wiring pattern provided on the element forming surface.

The foregoing arrangement provides better external connections to a pair of semiconductor chips and facilitates the designing of arrangement of the first and second electrode sections.

Alternatively, the aforementioned semiconductor integrated circuit device may be arranged so that some of the plurality of semiconductor chips, which are secured with the element forming surface facing opposite of the die pad, are each provided with external-connection-use second electrode sections, and

the second electrode sections receiving a common signal are connected to a common external-connection-use lead.

With the foregoing arrangement, the second electrode sections, of the semiconductor chips secured with the element forming surfaces thereof facing opposite of the die pad, receiving a common signal are connected together to a common external-connection-use lead. Consequently the leads can be reduced in number. The leads can be reduced greatly especially when some of the aforementioned semiconductor chips share a common function. As a result, the semiconductor integrated circuit device has a simpler arrangement, requires less cost to fabricate, and facilitates designing.

Alternatively, the aforementioned semiconductor integrated circuit device may be arranged so that a spacer is provided between the pair of the semiconductor chips to maintain an interval between the pair at a constant value.

With the foregoing arrangement, in an arrangement where the stacked semiconductor chips are sealed with a resin, the variation and balance of the interval between the stacked semiconductor chips can be improved. As a result, the semiconductor integrated circuit device can be sealed easily with a resin, and a semiconductor integrated circuit device of better quality is obtained.

The invention being thus described, it will be obvious that the same may be varied in many ways. Such variations are not to be regarded as a departure from the spirit and scope of the invention, and all such modifications as would be obvious to one skilled in the art intended to be included within the scope of the following claims.

What is claimed is:

1. A semiconductor integrated circuit device, comprising:
a first semiconductor chip provided on each side of a die pad so that a surface opposite to an element forming surface faces the die pad;
a multilayer structure provided on at least one side of the die pad, the structure including at least one semiconductor chip pair composed of the first semiconductor chip and a second semiconductor chip that is coupled to the first semiconductor chip so that the element forming surfaces of the first and second semiconductor chips face each other; and
a resin layer for sealing a stack body composed of the die pad and the first and second semiconductor chips.

2. The semiconductor integrated circuit device as set forth in claim 1,
wherein one semiconductor chip pair is provided on each side of the die pad.

3. The semiconductor integrated circuit device as set forth in claim 1,
wherein the second semiconductor chip in the semiconductor chip pair is electrically connected and coupled to the first semiconductor chip by a conductive coupling material, and
an external connection is provided to the first semiconductor chip and the second semiconductor chip by an external-connection-use electrode section provided on an end of the element forming surface of the first semiconductor chip.

4. The semiconductor integrated circuit device as set forth in claim 1, further comprising:
an external-connection-use electrode section provided on an end of the element forming surface of each first semiconductor chip; and
a plurality of leads for providing external connections to the first semiconductor chip and the second semiconductor chip,
wherein the electrode sections, of the first semiconductor chips, receiving a common signal are connected to the same lead.

5. The semiconductor integrated circuit device as set forth in claim 1, further comprising:
a spacer, provided between the first and second semiconductor chips, for maintaining an interval between the first and second semiconductor chips at a constant value.

6. The semiconductor integrated circuit device as set forth in claim 1,
wherein a resin coating film is provided between the resin layer and a surface of the stack body, the surface facing the resin layer.

7. A semiconductor integrated circuit device, comprising:
a plurality of semiconductor chips that are mounted thereon and sealed with a resin layer,
wherein the semiconductor chip is secured by a surface thereof opposite to an element forming surface onto either side of a die pad, and
at least a pair of the semiconductor chips are secured on at least one side of the die pad so that the element forming surfaces thereof face each other, and first electrode sections provided on the element forming surfaces are coupled together by a conductive coupling material.

8. The semiconductor integrated circuit device as set forth in claim 7,
wherein one of the pair of the semiconductor chips, which is closer to the die pad than the other, is provided on an end of the element forming surface thereof with external-connection-use second electrode sections, and
each of the second electrode sections is connected to one of the first electrode sections of the semiconductor chip that has the second electrode sections by a wiring pattern provided on the element forming surface.

9. The semiconductor integrated circuit device as set forth in claim 7,
wherein some of the plurality of semiconductor chips, which are secured with the element forming surface facing opposite of the die pad, are each provided with external-connection-use second electrode sections, and
the second electrode sections receiving a common signal are connected to a common external-connection-use lead.

10. The semiconductor integrated circuit device as set forth in claim 7,
wherein a spacer is provided between the pair of the semiconductor chips to maintain an interval between the pair at a constant value.
